(19) United States
(12) Patent Application Publication
(10) Pub. No.: US 2022/0075261 A1
(43) Pub. Date: Mar. 10, 2022

(54) LIGHT PANEL DISPLAY

(71) Applicant: Bugeye Technologies, Inc., Union, MO (US)

(72) Inventors: MICHAEL E. STOCKTON, Bland, MO (US); RICHARD W. HOMEYER, St. James, MO (US); ADAM L. MARQUART, Ballwin, MO (US)

(21) Appl. No.: 17/471,999

(22) Filed: Sep. 10, 2021

Related U.S. Application Data
(60) Provisional application No. 63/076,476, filed on Sep. 10, 2020.

(51) Int. Cl. G03F 1/80; G03F 1/76

(52) U.S. Cl. CPC G03F 1/80; G03F 1/76

(57) ABSTRACT

A light panel display and a method of manufacturing the light panel display are disclosed. The light panel display comprises a polyethylene terephthalate glycol panel adhered to the top of an acrylic panel, with paint applied to the top of the polyethylene terephthalate glycol panel. The paint layer is etched to provide for areas where light can pass through to convey information to a view of the panel. The light panel display, and its method of manufacture, provides for increased uniformity of lighting and ease of customization of the light panel display. The light panel display disclosed herein achieves uniform lighting through the construction and use of specific materials to diffuse light within the light panel display. The light panel display disclosed here is easily customizable through etching to form the mask that selectively allows light to pass out of the light panel display.

### CROSS-REFERENCE TO RELATED APPLICATIONS

This application claims priority to U.S. App. No. 63/076,476 filed Sep. 10, 2020, said application being incorporated herein by reference.

### STATEMENT REGARDING FEDERALLY SPONSORED RESEARCH

Not Applicable.

### BACKGROUND

The present disclosure relates to a light panel display and method of manufacturing a light panel display.

Light panel displays typically convey information with backlighting and may also light other features such as displays and/or controls extending through or embedded in the light panel display. Typically, a mask of substantially opaque material is backlit, with the mask selectively allowing light through by having sections of the mask material removed. The removed sections may form words, symbols, etc. which are visible as a result of the light passing through the mask.

Typical light panel displays are not readily customizable due to manufacturing techniques that do not readily allow for change in the layout or design of the light panel display being produced. Typical light panel displays also have uneven lighting and/or brightness. This may be caused, for example, by hardware behind the panel blocking a light source which can create shadows. Uneven lighting may also be caused by the materials and/or construction of the light display panel. For example, the material(s) used in the typical light display may unevenly disperse light.

### BRIEF SUMMARY

Briefly, a light panel display and a method of manufacturing a light panel display are disclosed. The light panel display, and its method of manufacture, provides for increased uniformity of lighting and ease of customization of the light panel display. The light panel display disclosed herein achieves uniform lighting through the construction and use of specific materials to diffuse light within the light panel display. The light panel display disclosed here is easily customizable through etching to form the mask that selectively allows light to pass out of the light panel display.

In accordance with an aspect of the light panel, the method of manufacturing a light display comprises bonding a polyethylene terephthalate glycol panel to a top side of an acrylic panel; applying a layer of paint to the top side of the polyethylene terephthalate glycol panel; and etching the layer of paint to form openings in the layer of paint to selectively reveal portions of the polyethylene terephthalate glycol panel in a desired pattern such that when the bottom side of the acrylic panel is illuminated at least some light passes through the acrylic panel, through the polyethylene terephthalate glycol panel, and through the openings in the layer of paint, the etching being selectively done such that the light passing through the openings in the layer of paint conveys information when viewed.

The method includes one or more of the following aspects:
The etching of the paint can be accomplished using one or more of laser etching, chemical etching, or mechanical etching.
The etching of the layer of paint leaves the polyethylene terephthalate glycol panel unetched.
The etching of the layer of paint includes etching and removing at least some material of the polyethylene terephthalate glycol panel.
The etching of the layer of paint leaves the acrylic panel unetched.
The acrylic material of the acrylic panel allows transmission of at least 85%, and preferably at least 92% percent of visible light.
The acrylic material of the acrylic panel is at least one of acrylic resin, poly methyl methacrylate, or acrylic thermoplastic.
The polyethylene terephthalate glycol panel comprises a glycol modified polyethylene terephthalate that allows transmission of between 80% and 86%, inclusive, of visible light.
The polyethylene terephthalate glycol panel is bonded directly to the top side of the acrylic panel.
The polyethylene terephthalate glycol panel is bonded directly to the top side of the acrylic panel by applying heat to the polyethylene terephthalate glycol panel, the acrylic panel, or both the polyethylene terephthalate glycol panel and the acrylic panel.
There are no intervening layers or material between the acrylic panel and the polyethylene terephthalate glycol panel, and there are no intervening layers or materials between the polyethylene terephthalate glycol panel and the layer of paint.
There are no intervening layers or material between the acrylic panel and the polyethylene terephthalate glycol panel other than an adhesive, and wherein there are no intervening layers or materials between the polyethylene terephthalate glycol panel and the layer of paint.
The acrylic panel has a first thickness between the bottom side and the top side thereof, and wherein polyethylene terephthalate glycol panel has a second thickness between the bottom side and the top side of the polyethylene terephthalate glycol panel, the first thickness of the acrylic panel being substantially greater than (and at least three times greater than) the second thickness of the polyethylene terephthalate glycol panel.
The first thickness of the acrylic panel is between three and six times the second thickness of the polyethylene terephthalate glycol panel, or is between four and five times the second thickness of the polyethylene terephthalate glycol panel, or is at least ten times the second thickness of the polyethylene terephthalate glycol panel.
The first thickness of the acrylic panel is substantially constant across the acrylic panel.
The second thickness of the polyethylene terephthalate glycol panel is substantially constant across the polyethylene terephthalate glycol panel.
The acrylic panel comprises a truncated conical shape extending upwardly through the polyethylene terephthalate glycol panel.

In accordance with another aspect, a light display panel made according to the above method is provided. The light display panel comprises a translucent acrylic panel adapted and configured to receive light from a light source and further adapted and configured to substantially and uniformly distribute light throughout the acrylic panel, a polyethylene terephthalate glycol panel bonded to the acrylic panel by a substantially transparent adhesive; and a layer of substantially opaque paint applied to the polyethylene terephthalate glycol panel. The layer of paint defines openings which expose the polyethylene terephthalate glycol panel, with the openings being in the shape of letters and/or symbols to convey information to a viewer when light is passed through the light display. The acrylic panel has a thickness substantially greater than (and at least three times greater than) a thickness of the polyethylene terephthalate glycol panel.

The light display panel can include one or more of the following aspects or characteristics:
The acrylic panel has a thickness that is between three and six times or between four and five time or at least ten times that of the polyethylene terephthalate glycol panel.
The adhesive is applied directly to the acrylic panel such that the polyethylene terephthalate glycol panel is bonded directly to the acrylic panel by the adhesive and such that only the adhesive is between the acrylic panel and the polyethylene terephthalate glycol panel, and wherein the layer of paint is applied directly to the polyethylene terephthalate glycol panel.
The acrylic panel comprises at least one of acrylic resin, poly methyl methacrylate, or acrylic thermoplastic.
The acrylic panel allows transmission of at least 85%, and preferably at least 92%, of visible light.
The polyethylene terephthalate glycol panel comprises a glycol modified polyethylene terephthalate that allows transmission of between 80% and 86%, inclusive, of visible light.
The adhesive allows transmission of at least 80 percent of visible light.

### DESCRIPTION OF THE DRAWINGS

In the accompanying drawings which form part of the specification:

FIG. 1 is a plan view of an illustrative light panel display;

FIG. 2 is a flowchart showing steps in the manufacturing of the light display panel;

FIGS. 3A-B are perspective and side plan views of an acrylic panel of a light display;

FIGS. 4A-B are perspective and side plan views of polyethylene terephthalate glycol panel with an adhesive applied to a bottom surface thereof;

FIGS. 5A-B are perspective and side plan views of the polyethylene terephthalate glycol panel bonded to the acrylic panel;

FIGS. 6A-B are perspective and side plan views of the acrylic panel and the polyethylene terephthalate glycol panel with a layer of paint applied to the polyethylene terephthalate glycol panel;

FIGS. 7A-B are perspective and side plan views of the acrylic panel, the polyethylene terephthalate glycol panel, and the layer of paint being etched with a laser;

FIGS. 8A-B are perspective and side plan views of the acrylic panel, the polyethylene terephthalate glycol panel, and the layer of paint with a portion of the layer of paint having been removed by etching;

FIG. 9 is a plan view of the acrylic panel, the polyethylene terephthalate glycol panel, and the layer of paint with a portion of the layer of paint having been removed by etching to form display text and symbols;

FIG. 10 is a plan view of a finished light display panel; and

FIGS. 11A-C are plan, side elevational, and perspective views of a layout of an illustrative light display panel.

### DETAILED DESCRIPTION

The following detailed description illustrates light panel displays and methods of manufacturing the light panel display by way of example and not by way of limitation. The description enables one skilled in the art to make and use the light panel display, describes several embodiments, adaptations, variations, alternatives, and uses of the light panel display, including what is presently believed to be the best mode of making and using the light panel display. Additionally, it is to be understood that the disclosed light panel display and method of manufacture are not limited to the details of construction and the arrangements of components set forth in the following description or illustrated in the drawings. The light panel display disclosed is capable of other embodiments and of being practiced or being carried out in various ways. Also, it is to be understood that the phraseology and terminology used herein is for the purpose of description and should not be regarded as limiting.

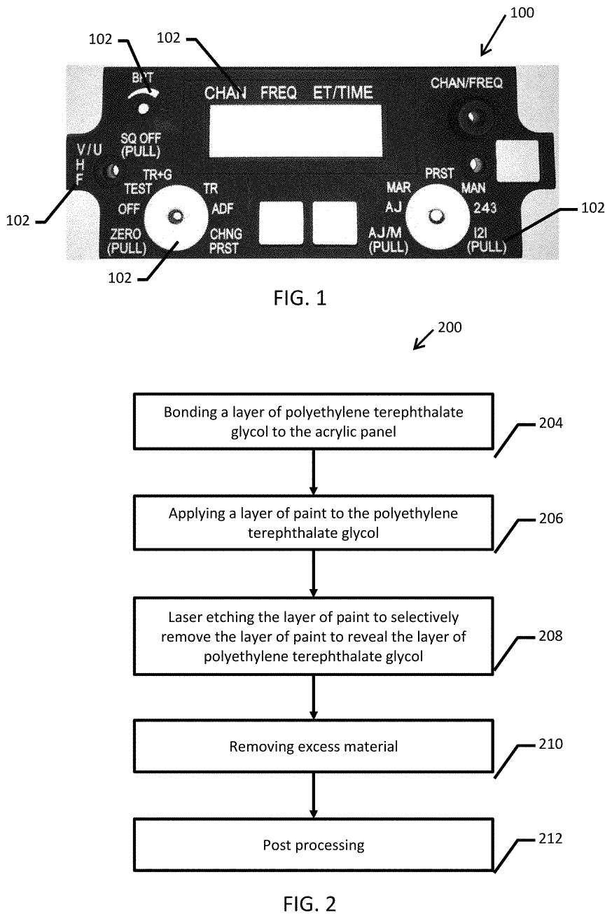

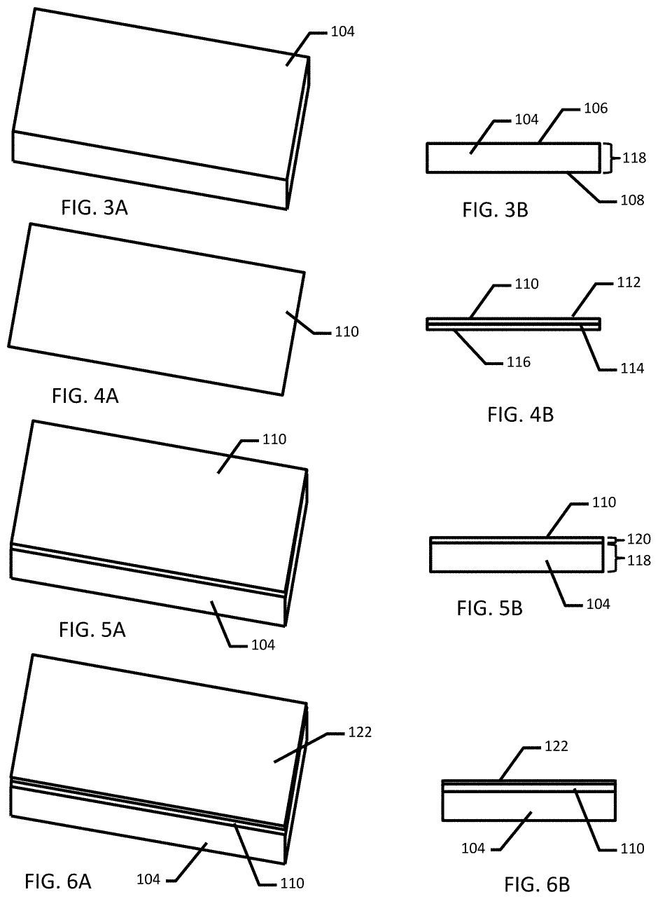

Referring generally to FIGS. 1-11, a light panel display 100 is shown and described. The light panel display 100 uses a combination of panels of polyethylene terephthalate glycol (PETG) and acrylic to provide diffuse and uniform lighting. Light entering the combination of materials from a light source (not shown) is diffused throughout the polyethylene terephthalate glycol and acrylic panels and then exits from the side opposite the light source to uniformly light the panel display 100. The light source may be any suitable light source that is controllable such that the brightness may be controlled (e.g., for the light panel display 100 to simulate a light panel display of an aircraft or other vehicle). For example, and without limitation, the light source can be an incandescent light, infrared light, ultraviolet light, one or more light emitting diodes (LEDs), or the like.

Light exiting the combination of polyethylene terephthalate glycol and acrylic panels is partially masked by a layer or layers of paint (e.g., black paint) or other substance with a low transmissivity or which is light opaque. The light allowed to pass through openings in the layer of paint, conveys information or illuminates controls or other features. For example, the layer of paint openings (areas without paint) in the shape of features 102 such as lettering, symbols, or the like such that the letter, symbols, etc. are illuminated against an opaque surrounding/background. Thus, the light panel display 100 communicates information through illuminated features and the blocking of light surrounding the illuminated features.

Referring now to FIG. 2, a flowchart 200 illustrates the steps in the method of manufacturing the light panel display 100. Initially, in step 204, a polyethylene terephthalate glycol (PETG) panel 110 (shown specifically in FIG. 4) is bonded to an acrylic panel 104. The acrylic panel 104 includes a top side 106 and a bottom side 108 opposite the top side 106. The acrylic panel 104 may start as a rectangular blank or may be already shaped to the final dimensions of the light panel display 100. The acrylic panel 104 comprises, for example, an acrylic material such as acrylic resin, poly methyl methacrylate, or acrylic thermoplastic. The acrylic panel 104 is substantially transparent, or preferably, clear. To that end, the acrylic panel 104 is preferably formed from an acrylic material that allows transmission of at least 85%, and preferably at least 92% visible light. More preferably, the acrylic panel 104 transmits at least 95% of visible light.

The polyethylene terephthalate glycol panel 110 is translucent (or semi-transparent). The polyethylene terephthalate glycol panel 110 includes a top side 112 and a bottom side 114 opposite the top side 112. The polyethylene terephthalate glycol panel is preferably made of a glycol modified polyethylene terephthalate that allows transmission of between 80% and 86%, inclusive, of visible light. More preferably, the polyethylene terephthalate glycol panel 110 allows transmission of 86% of visible light.

In the depicted embodiment (specifically FIGS. 4-5), the polyethylene terephthalate glycol panel 110 is bonded to the top side 106 of the acrylic panel 104 using an adhesive 116 which is clear. The adhesive 116 is applied to the bottom side 114 of the polyethylene terephthalate glycol panel 110. The polyethylene terephthalate glycol panel 110, with the adhesive 116 applied, is then bonded to the top side 106 of the acrylic panel 104. The adhesive 116 bonds the polyethylene terephthalate glycol panel 110 to the acrylic panel 104. The adhesive 116 may be any suitable adhesive that provides for transmission of visible light. For example, and without limitation, the adhesive 116 may be one or more of a cyanoacrylate (such as Loctite® 495), polyester urethane, acrylic urethane and polyether urethane, acrylic resins, polyester resins, polyvinyl alcohols, vinyl chloride-vinyl acetate copolymers, ethylene-vinyl acetate copolymers, polyimide resins, and/or epoxy resins. Even, double-sided tape can be used.

In alternative embodiments, the polyethylene terephthalate glycol panel 110 can be bonded to the acrylic panel 104 without the use of adhesive. For example, heat may be applied to the polyethylene terephthalate glycol penal 110, the acrylic panel 104, or both. As a result of the heating, the polyethylene terephthalate glycol panel 110 and the acrylic panel 104 are bonded together directly without any intervening layer of substance. In embodiments where adhesive 116 is used, there are preferably no other intervening layers or materials (other than the adhesive 116) between the polyethylene terephthalate glycol panel 110 and the acrylic panel 104.

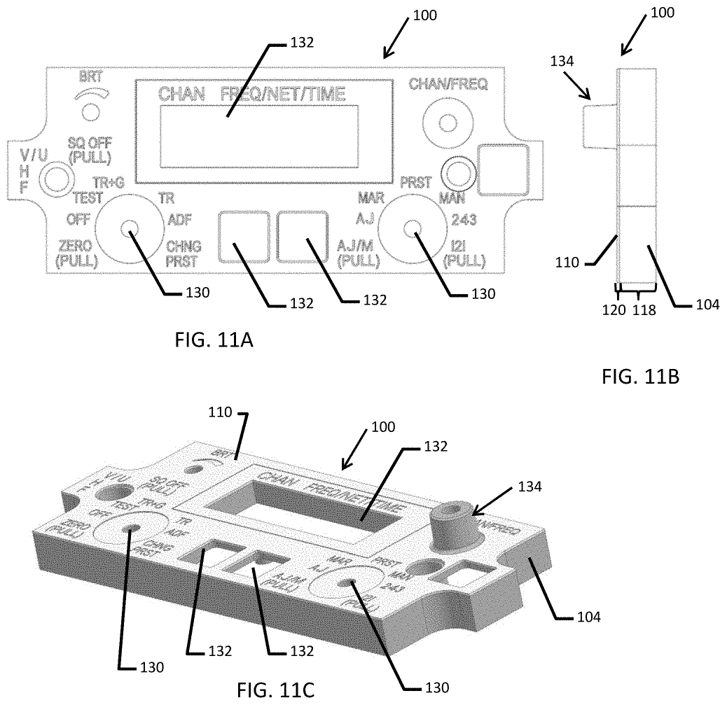

As a result of the bonding in step 204, the polyethylene terephthalate glycol panel 110 and the acrylic panel 104 are permanently bonded together (as shown in FIGS. 5A-B). The overall thickness of the light panel display 100 is a function of the combined thickness of the polyethylene terephthalate glycol panel 110 and the acrylic panel 104. The acrylic panel 104 has a first thickness 118 between the bottom side 108 and the top side 106. The polyethylene terephthalate glycol panel 110 has a second thickness 120 between the bottom side 114 and the top side 112. As seen in FIGS. 11B-C, the first thickness 118 of the acrylic panel 104 is substantially greater than the second thickness 120 of the polyethylene terephthalate glycol panel 110. The first thickness 118 may be between three and six times that of the second thickness 120. Alternatively, the first thickness 118 may be between four and five times the second thickness 120. In further alternatives, the first thickness 118 is at least ten times that of the second thickness 120. The thickness of the acrylic panel 104 relative to the thickness of the polyethylene terephthalate glycol panel 110 is selected to provide for uniform illumination of the display 100 through diffusion of input light throughout the acrylic panel 104. Illustratively, the acrylic panel can be 0.225″ think and the polyethylene terephthalate glycol panel 110 can be 0.025″ thick.

Referring now to FIGS. 2 and 6A-B, at step 206 of the method of manufacturing the light panel display 100, a layer of paint 122 is applied to the polyethylene terephthalate glycol panel 110. The layer of paint 122, as used herein, may include multiple layers of paint. The layer of paint 122 comprises a paint that is substantially opaque. The layer of paint 122 blocks substantially all light exiting the polyethylene terephthalate glycol panel 110 where the layer of paint 122 is applied. The layer of paint 122 is substantially thinner than the polyethylene terephthalate glycol panel 110. Alternatively, the layer of paint 122 can have the same or greater thickness as that of the polyethylene terephthalate glycol panel 110. The layer of paint 122 is initially applied to cover the entirety of the polyethylene terephthalate glycol panel 110.

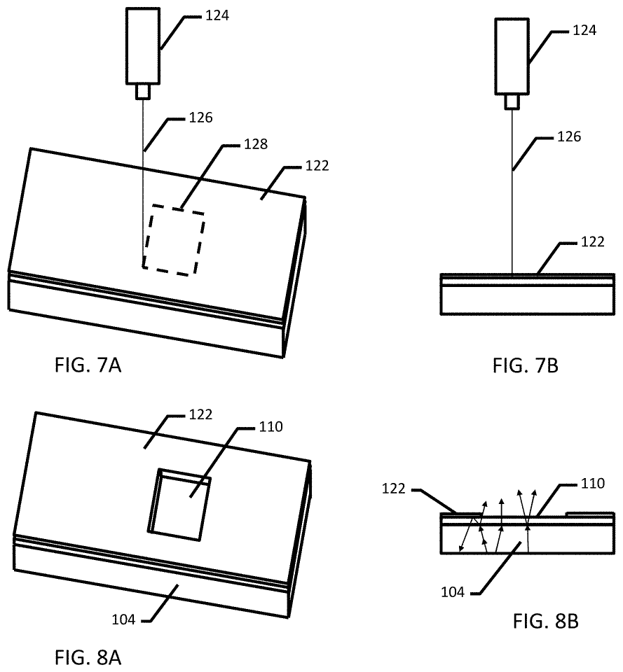

Referring now to FIGS. 2 and 7A-B, at step 208 of the method of manufacturing the light panel display 100, the layer of paint 122 is etched, preferably laser etched, to selectively remove portions of the layer of paint 122, and thereby create openings in the layer of paint 122, to reveal portions of the polyethylene terephthalate glycol panel 110. A laser 124 is used to apply a beam 126 to the layer of paint 122. The beam 126 etches, burns, vaporizes, or otherwise removes material from the layer of paint 122. By adjusting the power and/or duration of the beam 126 on the layer of paint 122, the amount of material removed may be controlled. The laser 124 is controlled such that the beam 126 is moved along an etching path 128. The etching path 128 is determined to produce openings in the shape of lettering, symbols, illumination pathway, or the like. In alternative embodiments, the layer of paint 122 can be etched using a technique other than laser etching. For example, the layer of paint 122 can be etched using chemical or mechanical etching.

As shown in FIGS. 8A-B, the etching of the layer of paint 122 results in exposing at least some of the polyethylene terephthalate glycol panel 110 to allow for light passing through the polyethylene terephthalate glycol panel 110 to be visible. Where the paint is present, light is absorbed and/or reflected back into the polyethylene terephthalate glycol panel 110 and/or the acrylic panel 104.

Ideally, etching the layer of paint 122 leaves the polyethylene terephthalate glycol panel 110 unetched. In other words, the laser, chemical agent, or mechanical tool does not remove any material from the polyethylene terephthalate glycol panel 110, and thus does not affect the thickness of the polyethylene terephthalate glycol panel 110. For example, the laser 124 may be controlled such that the focus, power, location, and/or duration of the laser beam 126 are such that the layer of paint 122 is removed, with the beam not removing any material of the polyethylene terephthalate glycol panel 110. In alternative embodiments, etching the layer of paint 122 includes etching and removing at least some material of the polyethylene terephthalate glycol panel 110. In any embodiment, the etching of the layer of paint 122 leaves the acrylic panel 104 unetched and covered by at least some of the polyethylene terephthalate glycol panel 110.

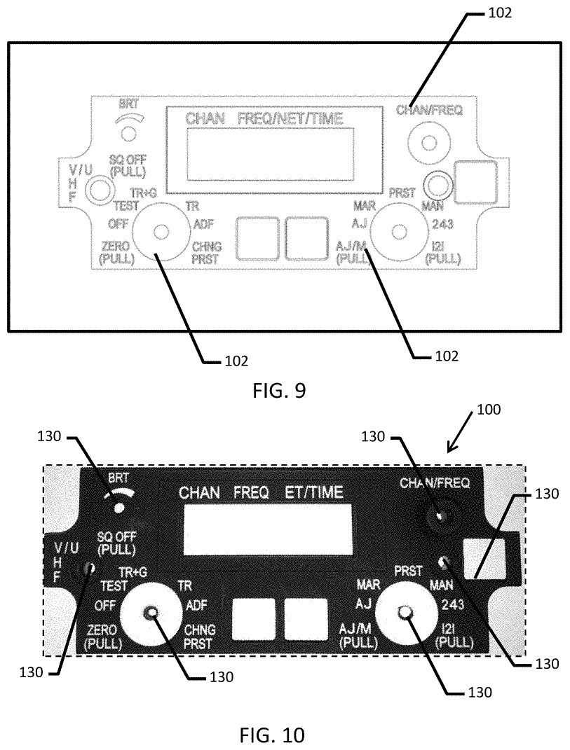

Referring now to FIG. 9, after etching the layer of paint 122 to selectively remove portions of the paint 122, the light panel display 100 has features 102 (e.g., lettering, symbols, illumination features, etc.) that are capable of being illuminated by a light source behind (beneath) the acrylic panel 104. Light may enter the acrylic panel 104, pass through the polyethylene terephthalate glycol panel 110, and pass through the openings in the layer of paint 122. These openings correspond with the features 102. Areas in which the layer of paint 122 has not been removed block transmission of light.

Referring to FIGS. 2 and 9, after etching, the assembly of the acrylic panel 104, the polyethylene terephthalate glycol panel 110, and the etched layer of paint 122 may not be the desired final overall shape of the light panel display 100. In such embodiments, the method of manufacturing includes step 210 in which excess material is removed. For example, the assembly of the acrylic panel 104, the polyethylene terephthalate glycol panel 110, and the etched layer of paint 122 may be milled to form the final shape of the light panel display (as shown in FIG. 10), with the light areas inside the perimeter (shown by dotted lines) being removed. In this instance, the perimeter of the paint layer will define the shape of the light display panel 100.

Referring to FIGS. 2 and 10, the method of manufacturing the light panel display 100 may additionally include one or more post processing steps 212. For example, one or more through holes 130 may be drilled or milled. Each through hole 130 may accommodate the shaft of a switch, dial, or the like. Additionally, polygonal (such as rectangular) openings 132 can be formed to accommodate switches, buttons, or particular display screens. Post processing may include further steps such as applying coatings, deburring edges, paint touch up, fitting a light source, or other steps to finalize the light panel display 100.

An illustrative light panel display is shown in FIGS. 11A-C. As seen, the display panel 100 is generally planar. The panel is provided with various openings 130 and 132 to accommodate dials, switches, buttons, displays, etc. In addition, the particular display panel shown has a projection 134. This projection 134 is part of the acrylic layer 104 and extends up through the polyethylene terephthalate glycol layer 110. As seen, the projection 134 has a hole extending downwardly from its top surface. This projection 134 can, for example, for the base for a knob, and the hole will then accept a shaft of the knob which is received by a control board beneath the display panel 100. As can be appreciated, light will pass into the knob supporting projection 134. Thus, the knob which is placed over the projection could have markings which are illuminated by the light passing into and through the projection 134.

As noted, this is an illustrative embodiment of a display panel 100. As can be appreciated, the overall shape of the display panel can vary, as can the number, position, and types of openings formed in the display panel. Finally, the display panel can be formed with more than the one projection, or it can have no projections. The shape and configuration (including holes and knob supporting projections) of the display panel will depend on the type of display being made.

The acrylic panel 104, as a result of its acrylic construction, may diffuse light entering from the bottom 108 from a light source. Diffusion of light through the acrylic panel 104 ensures even lighting of the light panel display 100. Diffusion of light throughout the acrylic panel 104 advantageously limits the negative impacts of hardware (e.g., switch components) that might otherwise block light from reaching the layer of paint 122 and the openings (selectively removed portions of paint) in the layer of paint 122. Thus, lettering, symbols, etc. of the light panel display are well lit. By using the specific material of polyethylene terephthalate glycol (or white polyethylene terephthalate glycol) bonded to the acrylic panel, light is uniformly dispersed across the light panel display 100 such that portions where the layer of paint 122 has been removed are uniformly lit. This is a result of the specific properties of the polyethylene terephthalate glycol panel alone and/or in combination with the specific properties of the acrylic panel 104 (e.g., the geometry, thickness, chemical properties, physical properties, etc.). The diffusivity of polyethylene terephthalate glycol enhances uniformity of the lighting of the light panel display 100. The combination of the polyethylene terephthalate glycol panel 110 and the acrylic panel 104 may also improve uniformity of lighting. For example, the refractive qualities resulting from the interface between the two different materials may improve uniformity of lighting.

Changes can be made in the above constructions without departing from the scope of the disclosure. It is intended that all matter contained in the above description or shown in the accompanying drawings shall be interpreted as illustrative and not in a limiting sense.

We claim:

1. A method of manufacturing a light display comprising:
bonding a polyethylene terephthalate glycol panel to a top side of an acrylic panel, the polyethylene terephthalate glycol panel having a top side;
applying a layer of paint to the top side of the polyethylene terephthalate glycol panel; and
etching the layer of paint to form openings in the layer of paint to selectively reveal portions of the polyethylene terephthalate glycol panel in a desired pattern such that when the bottom side of the acrylic panel is illuminated at least some light passes through the acrylic panel, through the polyethylene terephthalate glycol panel, and through the openings in the layer of paint, the etching being selectively done such that the light passing through the openings in the layer of paint conveys information when viewed.

2. The method of claim 1 wherein etching the layer of paint comprises etching the layer of paint using one or more of laser etching, chemical etching, or mechanical etching.

3. The method of claim 1 wherein etching the layer of paint leaves the polyethylene terephthalate glycol panel unetched.

4. The method of claim 1 wherein etching the layer of paint includes etching and removing at least some material of the polyethylene terephthalate glycol panel.

5. The method of claim 1 wherein etching the layer of paint leaves the acrylic panel unetched.

6. The method of claim 1 wherein the acrylic material of the acrylic panel allows transmission of at least 85% of visible light.

7. The method of claim 1 wherein the acrylic material of the acrylic panel is at least one of acrylic resin, poly methyl methacrylate, or acrylic thermoplastic.

8. The method of claim 1 wherein the polyethylene terephthalate glycol panel comprises a glycol modified polyethylene terephthalate that allows transmission of between 80% and 86%, inclusive, of visible light.

9. The method of claim 1 wherein the polyethylene terephthalate glycol panel is bonded directly to the top side of the acrylic panel.

10. The method of claim 9 wherein the polyethylene terephthalate glycol panel is bonded directly to the top side of the acrylic panel by applying heat to the polyethylene terephthalate glycol panel, the acrylic panel, or both the polyethylene terephthalate glycol panel and the acrylic panel.

11. The method of claim 1 wherein there are no intervening layers or material between the acrylic panel and the polyethylene terephthalate glycol panel, and wherein there are no intervening layers or materials between the polyethylene terephthalate glycol panel and the layer of paint.

12. The method of claim 1 wherein there are no intervening layers or material between the acrylic panel and the polyethylene terephthalate glycol panel other than an adhesive, and wherein there are no intervening layers or materials between the polyethylene terephthalate glycol panel and the layer of paint.

13. The method of claim 1 wherein the acrylic panel has a first thickness between the bottom side and the top side thereof, and wherein polyethylene terephthalate glycol panel has a second thickness between the bottom side and the top side of the polyethylene terephthalate glycol panel, the first thickness of the acrylic panel being at least three times the second thickness of the polyethylene terephthalate glycol panel.

14. The method of claim 13 wherein the first thickness of the acrylic panel is between three and six times the second thickness of the polyethylene terephthalate glycol panel.

15. The method of claim 13 wherein the first thickness of the acrylic panel is between four and five times the second thickness of the polyethylene terephthalate glycol panel.

16. The method of claim 13 wherein the first thickness of the acrylic panel is at least ten times the second thickness of the polyethylene terephthalate glycol panel.

17. The method of claim 13 wherein the first thickness of the acrylic panel is substantially constant across the acrylic panel.

18. The method of claim 13 wherein the second thickness of the polyethylene terephthalate glycol panel is substantially constant across the polyethylene terephthalate glycol panel.

19. The method of claim 1 wherein the acrylic panel comprises a truncated conical shape extending upwardly through the polyethylene terephthalate glycol panel.

20. A light display panel comprising:
a translucent acrylic panel adapted and configured to receive light from a light source and further adapted and configured to substantially and uniformly distribute light throughout the acrylic panel;
a polyethylene terephthalate glycol panel bonded to the acrylic panel by a substantially transparent adhesive; and
a layer of substantially opaque paint applied to the polyethylene terephthalate glycol panel, said layer of paint defining openings which expose the polyethylene terephthalate glycol panel, said openings being in the shape of letters and/or symbols to convey information to a viewer when light is passed through the light display,
wherein the acrylic panel has a thickness substantially greater than a thickness of the polyethylene terephthalate glycol panel.

21. The light display panel of claim 20 wherein the acrylic panel has a thickness that is between three and six times that of the polyethylene terephthalate glycol panel.

22. The light display panel of claim 20 wherein the acrylic panel has a thickness that is between four and five times that of the polyethylene terephthalate glycol panel.

23. The light display panel of claim 20 wherein the acrylic panel has a thickness that is at least ten times that of the polyethylene terephthalate glycol panel.

24. The light display panel of claim 20, wherein the adhesive is applied directly to the acrylic panel, the polyethylene terephthalate glycol panel is bonded directly to the acrylic panel by the adhesive, such that only the adhesive is between the acrylic panel and the polyethylene terephthalate glycol panel, and wherein the layer of paint is applied directly to the polyethylene terephthalate glycol panel.

25. The light display panel of claim 20, wherein the acrylic panel comprises at least one of acrylic resin, poly methyl methacrylate, or acrylic thermoplastic.

26. The light display panel of claim 20, wherein the acrylic panel allows transmission of at least 85% of visible light.

27. The light display panel of claim 20, wherein the polyethylene terephthalate glycol panel comprises a glycol modified polyethylene terephthalate that allows transmission of between 80% and 86%, inclusive, of visible light.

28. The light display panel of claim 20, wherein the adhesive allows transmission of at least 80 percent of visible light.
